(19) United States
(12) Patent Application Publication
(10) Pub. No.: US 2024/0262984 A1
(43) Pub. Date: Aug. 8, 2024

(54) COMPOSITION, CIRCUIT BOARD, AND METHOD FOR PRODUCING COMPOSITION

(71) Applicant: DAIKIN INDUSTRIES, LTD., Osaka (JP)

(72) Inventors: Kyouhei SAWAKI, Osaka (JP); Yuki UEDA, Osaka (JP); Shingo OKUNO, Osaka (JP); Mayuko TATEMICHI, Osaka (JP)

(73) Assignee: DAIKIN INDUSTRIES, LTD., Osaka (JP)

(21) Appl. No.: 18/627,638

(22) Filed: Apr. 5, 2024

Related U.S. Application Data
(63) Continuation of application No. PCT/JP2022/037814, filed on Oct. 11, 2022.

(30) Foreign Application Priority Data
Oct. 13, 2021 (JP) 2021-168125

(51) Int. Cl. C08K 5/3492; C08J 3/20; C08K 3/36; C08K 5/3475; H05K 1/03

(52) U.S. Cl. CPC C08K 5/3492; C08J 3/201; C08K 3/36; C08K 5/3475; H05K 1/0346; C08J 2327/18

(57) ABSTRACT

The disclosure aims to provide a composition having excellent UV laser processibility, a circuit board, and a method for producing a composition. The composition contains a fluororesin and a nitrogen-containing heterocyclic compound having a 18 by mass reduction temperature during pyrolysis of 330° C. or higher, and has an absorbance of light with a wavelength of 355 nm of 0.6 or higher.

### CROSS REFERENCE TO RELATED APPLICATIONS

This application is a Rule 53 (b) Continuation of International Application No. PCT/JP2022/037814 filed Oct. 11 2022, which claims priority from Japanese patent application No. 2021-168125 filed Oct. 13, 2021, the respective disclosures of which are incorporated herein by reference in their entireties.

### TECHNICAL FIELD

The disclosure relates to compositions, circuit boards, and methods for producing a composition.

### BACKGROUND ART

Speeding up of communication generates a demand for low dielectric, low loss materials for circuit boards to be used in devices such as electrical devices, electronic devices, and communication devices. Fluororesins are examined as these materials, but fluororesins need improvement in that they are less likely to absorb ultraviolet rays and they have poor UV laser processibility.

Patent Literature 1 discloses, as a technique for improving the ultraviolet absorbency of fluororesin, a technique of adding a metal oxide such as titanium oxide to a fluororesin.

### CITATION LIST

### Patent Literature

Patent Literature 1: JP 2020-37662 A

### SUMMARY

The disclosure (1) relates to a composition containing: a fluororesin; and a nitrogen-containing heterocyclic compound having a 1% by mass reduction temperature during pyrolysis of 330° C. or higher, and having an absorbance of light with a wavelength of 355 nm of 0.6 or higher (hereinafter, also referred to as the “composition of the disclosure”).

### Advantageous Effects

The disclosure can provide a composition having excellent UV laser processibility, a circuit board, and a method for producing a composition.

### DESCRIPTION OF EMBODIMENTS

The “organic group” herein means a group containing at least one carbon atom or a group formed by removing one hydrogen atom from an organic compound.

Examples of this “organic group” include
an alkyl group optionally containing at least one substituent,
an alkenyl group optionally containing at least one substituent,
an alkynyl group optionally containing at least one substituent,
a cycloalkyl group optionally containing at least one substituent,
a cycloalkenyl group optionally containing at least one substituent,
a cycloalkadienyl group optionally containing at least one substituent,
an aryl group optionally containing at least one substituent,
an aralkyl group optionally containing at least one substituent,
a non-aromatic heterocyclic group optionally containing at least one substituent,
a heteroaryl group optionally containing at least one substituent,
a cyano group,
a formyl group,
RaO—,
RaCO—,
RaSO₂—,
RaCOO—,
RaNRaCO—,
RaCONRa-,
RaoCO—,
RaOSO₂—, and
RaNRbSO₂—,
wherein the Ra groups are each independently
an alkyl group optionally containing at least one substituent,
an alkenyl group optionally containing at least one substituent,
an alkynyl group optionally containing at least one substituent,
a cycloalkyl group optionally containing at least one substituent,
a cycloalkenyl group optionally containing at least one substituent,
a cycloalkadienyl group optionally containing at least one substituent,
an aryl group optionally containing at least one substituent,
an aralkyl group optionally containing at least one substituent,
a non-aromatic heterocyclic group optionally containing at least one substituent, or
a heteroaryl group optionally containing at least one substituent; and
the Rb groups are each independently H or an alkyl group optionally containing at least one substituent.

The organic group is preferably an alkyl group optionally containing at least one substituent.

The disclosure will be specifically described hereinbelow.

The composition of the disclosure contains a fluororesin and a nitrogen-containing heterocyclic compound having a 1% by mass reduction temperature during pyrolysis of 330° C. or higher, and has an absorbance of light with a wavelength of 355 nm of 0.6 or higher.

Owing to the presence of the nitrogen-containing heterocyclic compound, the composition of the disclosure has high absorbance and excellent UV laser processibility while containing a fluororesin.

Adding a metal oxide such as titanium oxide, as disclosed in Patent Literature 1, may impair the electric properties of the fluororesin. In contrast, the nitrogen-containing heterocyclic compound has advantageously less influence on the electric properties.

Further, the nitrogen-containing heterocyclic compound is less likely to cause pyrolysis and can thus be mixed with a fluororesin by melt kneading. Melt kneading allows the nitrogen-containing heterocyclic compound to well disperse in a fluororesin, leading to much improved UV laser processibility.

The fluororesin used may be a polymer of tetrafluoroethylene (TFE) or a copolymer of TFE and a copolymerizable monomer copolymerizable with TFE.

The copolymerizable monomer may be any monomer copolymerizable with TFE, and examples thereof include hexafluoropropylene (HFP), a fluoroalkyl vinyl ether, a fluoroalkyl ethylene, a fluoromonomer represented by the formula (100): CH₂═CFRf¹⁰¹ (wherein Rf¹⁰¹ is a C1-C12 linear or branched fluoroalkyl group), and a fluoroalkyl allyl ether.

The fluoroalkyl vinyl ether preferably includes at least one selected from the group consisting of:
a fluoromonomer represented by the formula (110):

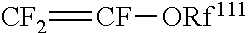

wherein Rf¹¹¹ is a perfluoro organic group;
a fluoromonomer represented by the formula (120):

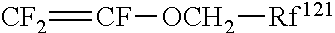

wherein Rf¹²¹ is a C1-C5 perfluoroalkyl group;
a fluoromonomer represented by the formula (130):

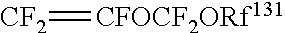

wherein Rf¹³¹ is a C1-C6 linear or branched perfluoroalkyl group, a C5-C6 cyclic perfluoroalkyl group, or a C2-C6 linear or branched perfluorooxyalkyl group containing one to three oxygen atoms; 30
a fluoromonomer represented by the formula (140):

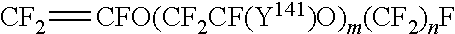

wherein Y¹⁴¹ is a fluorine atom or a trifluoromethyl group; m is an integer of 1 to 4; and n is an integer of 1 to 4; and
a fluoromonomer represented by the formula (150):

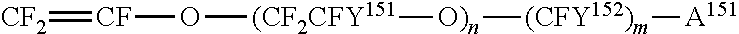

wherein Y¹⁵¹ is a fluorine atom, a chlorine atom, a —SO₂F group, or a perfluoroalkyl group, where the perfluoroalkyl group optionally contains ether oxygen and a —SO₂F group; n is an integer of 0 to 3; n Y¹⁵¹s are the same as or different from each other; Y¹⁵² is a fluorine atom, a chlorine atom, or a —SO₂F group; m is an integer of 1 to 5; m Y¹⁵²s are the same as or different from each other; and A¹⁵¹ is —SO₂X¹⁵¹, —COZ¹⁵¹, or —POZ¹⁵²Z¹⁵³, where X¹⁵¹ is F, Cl, Br, I, —OR¹⁵¹, or —NR¹⁵²R¹⁵³, and Z¹⁵¹, Z¹⁵², and Z¹⁵³ are the same as or different from each other and are each —NR¹⁵⁴R¹⁵⁵ or —OR¹⁵⁶, and where R¹⁵¹, R¹⁵², R¹⁵³, R¹⁵⁴, R¹⁵⁵, and R¹⁵⁶ are the same as or different from each other and are each H, ammonium, an alkali metal, or an alkyl group, aryl group, or sulfonyl-containing group optionally containing a fluorine atom.

The “perfluoro organic group” herein means an organic group in which all hydrogen atoms bonded to any carbon atom are replaced by fluorine atoms. The perfluoro organic group may have ether oxygen.

An example of the fluoromonomer represented by the formula (110) may be a fluoromonomer in which Rf¹¹¹ is a C1-C10 perfluoroalkyl group. The carbon number of the perfluoroalkyl group is preferably 1 to 5.

Examples of the perfluoro organic group in the formula (110) include a perfluoromethyl group, a perfluoroethyl group, a perfluoropropyl group, a perfluorobutyl group, a perfluoropentyl group, and a perfluorohexyl group.

Examples of the fluoromonomer represented by the formula (110) also include:
a monomer represented by the formula (110) in which Rf¹¹¹ is a C4-C9 perfluoro (alkoxyalkyl) group;
a monomer in which Rf¹¹¹ is a group represented by the following formula:

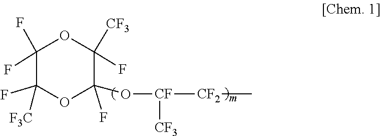

wherein m is 0 or an integer of 1 to 4; and
a monomer in which Rf¹¹¹ is a group represented by the following formula:

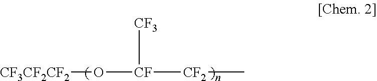

wherein n is an integer of 1 to 4.

In particular, the fluoromonomer represented by the formula (110) is preferably a perfluoro (alkyl vinyl ether) (PAVE), more preferably a fluoromonomer represented by the formula (160):

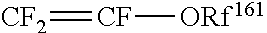

wherein Rf¹⁶¹ is a C1-C10 perfluoroalkyl group. Rf¹⁶¹ is preferably a C1-C5 perfluoroalkyl group.

The fluoroalkyl vinyl ether preferably includes at least one selected from the group consisting of fluoromonomers represented by any of the formulas (160), (130), and (140).

The fluoromonomer (PAVE) represented by the formula (160) preferably includes at least one selected from the group consisting of perfluoro(methyl vinyl ether) (PMVE), perfluoro (ethyl vinyl ether) (PEVE), and perfluoro (propyl vinyl ether) (PPVE), more preferably includes at least one selected from the group consisting of perfluoro(methyl vinyl ether) and perfluoro (propyl vinyl ether).

The fluoromonomer represented by the formula (130) preferably includes at least one selected from the group consisting of CF₂═CFOCF₂OCF₃, CF₂═CFOCF₂OCF₂CF₃, and CF₂═CFOCF₂OCF₂CF₂OCF₃.

The fluoromonomer represented by the formula (140) preferably includes at least one selected from the group consisting of CF₂═CFOCF₂CF(CF₃)O(CF₂)₃F, CF₂═CFO(CF₂CF(CF₃)O)₂(CF₂)₃F, and CF₂═CFO(CF₂CF(CF₃)O)₂(CF₂)₂F.

The fluoromonomer represented by the formula (150) preferably includes at least one selected from the group consisting of CF₂═CFOCF₂CF₂SO₂F, CF₂═CFOCF₂CF(CF₃)OCF₂CF₂SO₂F, CF₂═CFOCF₂CF(CF₂CF₂SO₂F)OCF₂CF₂SO₂F, and CF₂═CFOCF₂CF(SO₂F)₂.

The fluoromonomer represented by the formula (100) is preferably a fluoromonomer in which Rf¹⁰¹ is a linear fluoroalkyl group, more preferably a fluoromonomer in which Rf¹⁰¹ is a linear perfluoroalkyl group. Rf¹⁰¹ preferably has a carbon number of 1 to 6. Examples of the fluoromonomer represented by the formula (100) include CH₂═CFCF₃, CH₂═CFCF₂CF₃, CH₂═CFCF₂CF₂CF₃, CH₂═CFCF₂CF₂CF₂H, CH₂═CFCF₂CF₂CF₂CF₃, CHF═CHCF₃ (E configuration), and CHF═CHCF₃ (Z configuration). Preferred among these is 2,3,3,3-tetrafluoropropylene represented by CH₂═CFCF₃.

The fluoroalkylethylene is preferably a fluoroalkylethylene represented by the formula (170):

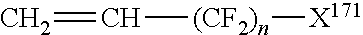

(wherein X¹⁷¹ is H or F; and n is an integer of 3 to 10); and more preferably includes at least one selected from the group consisting of CH₂═CH—C₄F₉ and CH₂═CH—C₆F₁₃.

An example of the fluoroalkyl allyl ether may be a fluoromonomer represented by the formula (180):

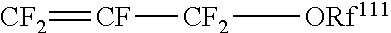

wherein Rf¹¹¹ is a perfluoro organic group.
Rf¹¹¹ of the formula (180) is defined as described for Rf¹¹¹ of the formula (110). Rf¹¹¹ is preferably a C1-C10 perfluoroalkyl group or a C1-C10 perfluoroalkoxyalkyl group. The fluoroalkyl allyl ether represented by the formula (180) preferably includes at least one selected from the group consisting of CF₂═CF—CF₂—O—CF₃, CF₂═CF—CF₂—O—C₂F₅, CF₂═CF—CF₂—O—C₃F₇, and CF₂═CF—CF₂—O—C₄F₉, more preferably includes at least one selected from the group consisting of CF₂═CF—CF₂—O—C₂F₅, CF₂═CF—CF₂—O—C₃F₇, and CF₂═CF—CF₂—O—C₄F₉, and is still more preferably CF₂—CF—CF₂—O—CF₂CF₂CF₃.

To achieve less deformation and a lower linear expansion coefficient of the composition, the copolymerizable monomer is preferably a monomer containing a perfluorovinyl group, more preferably includes at least one selected from the group consisting of a perfluoro (alkyl vinyl ether) (PAVE), hexafluoropropylene (HFP), and perfluoroallyl ether, still more preferably includes at least one selected from the group consisting of PAVE and HFP. To reduce deformation of the composition during soldering, PAVE is particularly preferred.

The fluororesin preferably contains a unit of the copolymerizable monomer in a total amount of 0.1% by mass or more, more preferably 1.0% by mass or more, still more preferably 1.1% by mass or more of all monomer units. The total amount of the copolymerizable monomer unit is also preferably 30% by mass or less, more preferably 20% by mass or less, still more preferably 15% by mass or less of all monomer units.

The amount of the copolymerizable monomer unit is determined by ¹⁹F-NMR.

To achieve less deformation of the composition and a lower linear expansion coefficient of the composition, the fluororesin preferably includes at least one selected from the group consisting of a tetrafluoroethylene (TFE)/perfluoro (alkyl vinyl) ether (PAVE) copolymer (PFA) and a tetrafluoroethylene (TFE)/hexafluoropropylene (HFP) copolymer (FEP).

In the case where the fluororesin is PFA containing a TFE unit and a PAVE unit, the PAVE unit is preferably contained in an amount of 0.1 to 12% by mass of all polymerized units. The amount of the PAVE unit is more preferably 0.3% by mass or more, still more preferably 0.7% by mass or more, further preferably 1.0% by mass or more, particularly preferably 1.1% by mass or more, while more preferably 8.0% by mass or less, still more preferably 6.5% by mass or less, particularly preferably 6.0% by mass or less of all polymerized units.

The amount of the PAVE unit is determined by ¹⁹F-NMR.

In the case where the fluororesin is FEP containing a TFE unit and a HFP unit, the TFE unit and the HFP unit preferably have a mass ratio (TFE/HFP) of (70 to 99)/(1 to 30) (% by mass). The mass ratio (TFE/HFP) is more preferably (85 to 95)/(5 to 15) (% by mass).

The FEP contains the HFP unit in an amount of 1% by mass or more, preferably 1.1% by mass or more of all monomer units.

The FEP preferably contains a perfluoro (alkyl vinyl ether) (PAVE) unit as well as the TFE unit and the HFP unit.

Examples of the PAVE unit contained in the FEP include the same as the PAVE units to form the aforementioned PFA. Preferred among these is PPVE.

The aforementioned PFA contains no HFP unit and is therefore different from the FEP containing a PAVE unit in this respect.

In the case where the FEP contains a TFE unit, a HFP unit, and a PAVE unit, they preferably have a mass ratio (TFE/HFP/PAVE) of (70 to 99.8)/(0.1 to 25)/(0.1 to 25) (% by mass). The FEP having a mass ratio within this range can have excellent heat resistance and excellent chemical resistance.

The mass ratio (TFE/HFP/PAVE) is more preferably (75 to 98)/(1.0 to 15)/(1.0 to 10) (% by mass).

The FEP contains the HFP unit and the PAVE unit in a total amount of 1% by mass or more, preferably 1.1% by mass or more of all monomer units.

The FEP containing a TFE unit, a HFP unit, and a PAVE unit preferably contains the HFP unit in an amount of 25% by mass or less of all monomer units.

The HFP unit contained in an amount within this range can lead to a composition having excellent heat resistance.

The amount of the HFP unit is more preferably 20% by mass or less, still more preferably 18% by mass or less, particularly preferably 15% by mass or less. The amount of the HFP unit is also preferably 0.1% by mass or more, more preferably 1% by mass or more, particularly preferably 2% by mass or more.

The amount of the HFP unit can be determined by ¹⁹F-NMR.

The amount of the PAVE unit is more preferably 20% by mass or less, still more preferably 10% by mass or less, particularly preferably 3% by mass or less. The amount of the PAVE unit is also preferably 0.1% by mass or more, more preferably 1% by mass or more. The amount of the PAVE unit can be determined by ¹⁹F-NMR.

The FEP may further contain a different ethylenic monomer (α) unit.

The different ethylenic monomer (a) unit may be any monomer unit copolymerizable with TFE, HFP, and PAVE. Examples thereof include fluorine-containing ethylenic monomers such as vinyl fluoride (VF), vinylidene fluoride (VdF), chlorotrifluoroethylene (CTFE), and ethylene (Et) and non-fluorinated ethylenic monomers such as ethylene, propylene, and alkyl vinyl ethers.

In the case where the FEP contains a TFE unit, a HFP unit, a PAVE unit, and a different ethylenic monomer (α) unit, they preferably have a mass ratio (TFE/HFP/PAVE/different ethylenic monomer (α)) of (70 to 98)/(0.1 to 25)/(0.1 to 25)/(0.1 to 25) (% by mass).

The FEP contains the monomer units excluding the TFE unit in a total amount of 1% by mass or more, preferably 1.1% by mass or more of all monomer units.

The fluororesin also preferably includes the PFA and the FEP. In other words, the PFA and the FEP may be used as a mixture thereof. The PFA and the FEP preferably have a mass ratio (PFA/FEP) of 9/1 to 3/7, more preferably 9/1 to 5/5.

The PFA and the FEP each may be produced, for example, by a conventionally known method in which monomers to serve as the structural units and additives such as a polymerization initiator are mixed as appropriate, followed by emulsion polymerization or suspension polymerization.

The fluororesin preferably has a melting point of 240° C. to 320° C. This enables easy melt kneading.

The melting point of the fluororesin is more preferably 318° C. or lower, still more preferably 315° C. or lower, while more preferably 245° C. or higher, still more preferably 250° C. or higher.

The melting point of the fluororesin is the temperature corresponding to the maximum value on a heat-of-fusion curve with a temperature-increasing rate of 10° C./min using a differential scanning calorimeter (DSC). The fluororesin preferably has a melt flow rate (MFR) at 372° C. of 0.1 to 100 g/10 min. This enables easy melt kneading.

The MFR is more preferably 0.5 g/10 min or higher, while more preferably 80 g/10 min or lower, still more preferably 40 g/10 min or lower.

The MFR is a value obtained as the mass (g/10 min) of a polymer flowing out of a nozzle (inner diameter: 2 mm, length: 8 mm) per 10 minutes at a temperature of 372° C. and a load of 5 kg using a melt indexer (available from Yasuda Seiki Seisakusho Ltd.) in conformity with ASTM D1238.

The fluororesin may have any relative permittivity and any dissipation factor. The relative permittivity at 25° C. and a frequency of 10 GHz is preferably 4.5 or lower, more preferably 4.0 or lower, still more preferably 3.5 or lower, particularly preferably 2.5 or lower. The dissipation factor is 0.01 or lower, preferably 0.008 or lower, more preferably 0.005 or lower.

The fluororesin is contained in an amount of preferably 60% by mass or more, more preferably 70% by mass or more, still more preferably 80% by mass or more, while preferably 99.9% by mass or less, more preferably 99.0% by mass or less of the composition.

The nitrogen-containing heterocyclic compound has a 1% by mass reduction temperature during pyrolysis (hereinafter, also referred to as the 1% pyrolysis temperature) of 330° C. or higher.

To perform melt kneading easily, the lower limit of the 1% pyrolysis temperature is preferably 340° C., more preferably 350° C. The upper limit is not limited.

The 1% pyrolysis temperature is determined using a thermal analyzer STA7200 available from Hitachi High-Tech Corp. The measurement is performed in an atmosphere purged with nitrogen at 200 mL/min. A 10-mg portion of a sample is put into an aluminum pan and maintained at 25° C. for 10 minutes, followed by temperature rise at a temperature-increasing rate of 10° C./min up to 600° C. Based on the initial mass, the 1% mass reduction temperature is defined as the 1% pyrolysis temperature.

The nitrogen-containing heterocyclic compound is preferably a non-polymeric nitrogen-containing heterocyclic compound. In the case of a polymeric compound, the melt-kneaded composition may be difficult to form a film; In the case of a non-polymeric compound, even the melt-kneaded composition can be easily formed into a film.

The non-polymeric nitrogen-containing heterocyclic compound may be any compound that is not a polymer.

The nitrogen-containing heterocyclic compound preferably has a molecular weight of 1200 g/mol or lower. This allows even the melt-kneaded composition to be easily formed into a film.

The upper limit of the molecular weight is more preferably 1100 g/mol, still more preferably 1000 g/mol, while the lower limit thereof is more preferably 50 g/mol, still more preferably 100 g/mol.

The nitrogen-containing heterocyclic compound preferably contains a nitrogen-containing heterocycle. This can lead to excellent light absorbability.

Preferably, the nitrogen-containing heterocycle is a 3- to 10-membered nitrogen-containing heterocycle and contains a total of two or more nitrogen and oxygen atoms. This can provide excellent light absorbability to the nitrogen-containing heterocyclic compound and can lead to improved blending of the nitrogen-containing heterocyclic compound and a resin.

The nitrogen-containing heterocycle is more preferably a four- or more-membered heterocycle, still more preferably a five- or more-membered heterocycle, while more preferably a nine- or less-membered heterocycle, still more preferably an eight- or less-membered heterocycle.

The total number of nitrogen and oxygen atoms contained in the nitrogen-containing heterocycle is preferably five or less, more preferably four or less, still more preferably three or less, particularly preferably three.

The total number of nitrogen and oxygen atoms described above is counted for only the ring-forming atoms of the nitrogen-containing heterocycle, not containing those in the substituents of the nitrogen-containing heterocycle.

Specific examples of the nitrogen-containing heterocycle include a triazine ring, a benzotriazole ring, an oxazine ring, a benzoxazine ring, an imidazole ring, an oxazole ring, a tetrazole ring, a pyrimidine ring, and a pyrazine ring. Preferred among these are a triazine ring, a benzotriazole ring, and a benzoxazine ring, with a triazine ring more preferred. The triazine ring may be any of a 1,2,3-triazine ring, a 1,2,4-triazine ring, and a 1,3,5-triazine ring, and is preferably a 1,3,5-triazine ring.

One of the nitrogen-containing heterocycles may be contained or two or more thereof may be contained.

Preferably, one to three nitrogen-containing heterocycles are contained in one molecule of the nitrogen-containing heterocyclic compound. The number of the nitrogen-containing heterocycles is more preferably one or two, still more preferably one.

In the case of a condensed ring such as a benzotriazole ring, this condensed ring is counted as one ring.

The nitrogen-containing heterocyclic compound preferably further contains an aromatic ring different from the nitrogen-containing heterocycle. This can lead to excellent light absorbability.

The number of the aromatic rings is preferably 3 or more, more preferably 4 or more, still more preferably 5 or more, while preferably 10 or less, more preferably 8 or less, still more preferably 6 or less.

Specific examples of the aromatic ring include a benzene ring and a naphthalene ring. Preferred is a benzene ring.

One of the aromatic rings may be contained or two or more thereof may be contained.

Preferably, one to five aromatic rings are contained in one molecule of the nitrogen-containing heterocyclic compound. The number of the aromatic rings is more preferably two to five, still more preferably three to five.

In the case of a condensed ring such as a naphthalene ring, this condensed ring is counted as one ring.

The nitrogen-containing heterocycle and the aromatic ring each may contain a substituent.

Examples of the substituent include, but are not limited to, an alkyl group, an alkoxy group, a hydroxy group, an oxo group (═O), a carboxy group, an amino group, and a halogen atom. Preferred among these are an alkyl group, an alkoxy group, a hydroxy group, and an oxo group.

One of the substituents may be used or two or more thereof may be used.

In each of the nitrogen-containing heterocycle and the aromatic ring, the number of the substituents is preferably five or less, more preferably three or less, still more preferably two or less, and may be zero.

The alkyl group may be linear, branched, or cyclic.

The carbon number of the alkyl group is preferably 1 or more, while preferably 10 or less, more preferably 8 or less.

The alkoxy group is a group in which the alkyl group is bonded to an oxygen atom.

The carbon number of the alkyl group bonded in the alkoxy group is preferably 1 or more, more preferably 3 or more, while preferably 10 or less, more preferably 8 or less.

The nitrogen-containing heterocyclic compound suitably used may be a compound having a structure represented by the following formula (1):

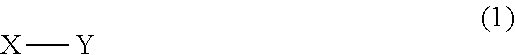

wherein X is a nitrogen-containing heterocycle; Y is an aromatic ring different from the nitrogen-containing heterocycle; and X and Y each optionally have a substituent.

In the formula (1), the nitrogen-containing heterocycle represented by X and the aromatic ring represented by Y are defined as described above.

Also, in the formula (1), X and Y may be directly bonded or may be bonded via a substituent such as the alkyl group.

The compound having a structure represented by the formula (1) suitably used may be a compound represented by the following formula (2A) or a compound represented by the following formula (2B):

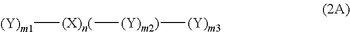

wherein X and Y are defined as in the formula (1); n is an integer of 1 to 3; m1, m2, and m3 are each an integer of 0 to 5, with at least one of m1, m2, or m3 being not 0; when multiple Xs are present, they are the same as or different from each other; and when multiple Ys are present, they are the same as or different from each other,

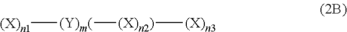

wherein X and Y are defined as in the formula (1); n1, n2, and n3 are each an integer of 0 to 3, with at least one of n1, n2, or n3 being not 0; m is an integer of 1 to 5; when multiple Xs are present, they are the same as or different from each other; and when multiple Ys are present, they are the same as or different from each other.

When multiple Xs are present in the formulas (2A) and (2B), they may be directly bonded or may be bonded via a substituent such as the alkyl group. The same applies to the case where multiple Ys are present.

In the formula (2A), n is preferably 1 or 2, more preferably 1; m1, m2, and m3 are each preferably 1 or 2; and particularly preferably, one of n1, n2, and n3 is 1 while the remaining two of these are 1 or 2.

Specific examples of the compound represented by the formula (2A) include the compounds represented by any of the following formulas (2A-1) to (2A-4). Specific examples of commercially available products of the compounds represented by these formulas include Tinuvin 1600 available from BASF Japan Ltd. and ADK STAB LA-F70 available from Adeka Corp.

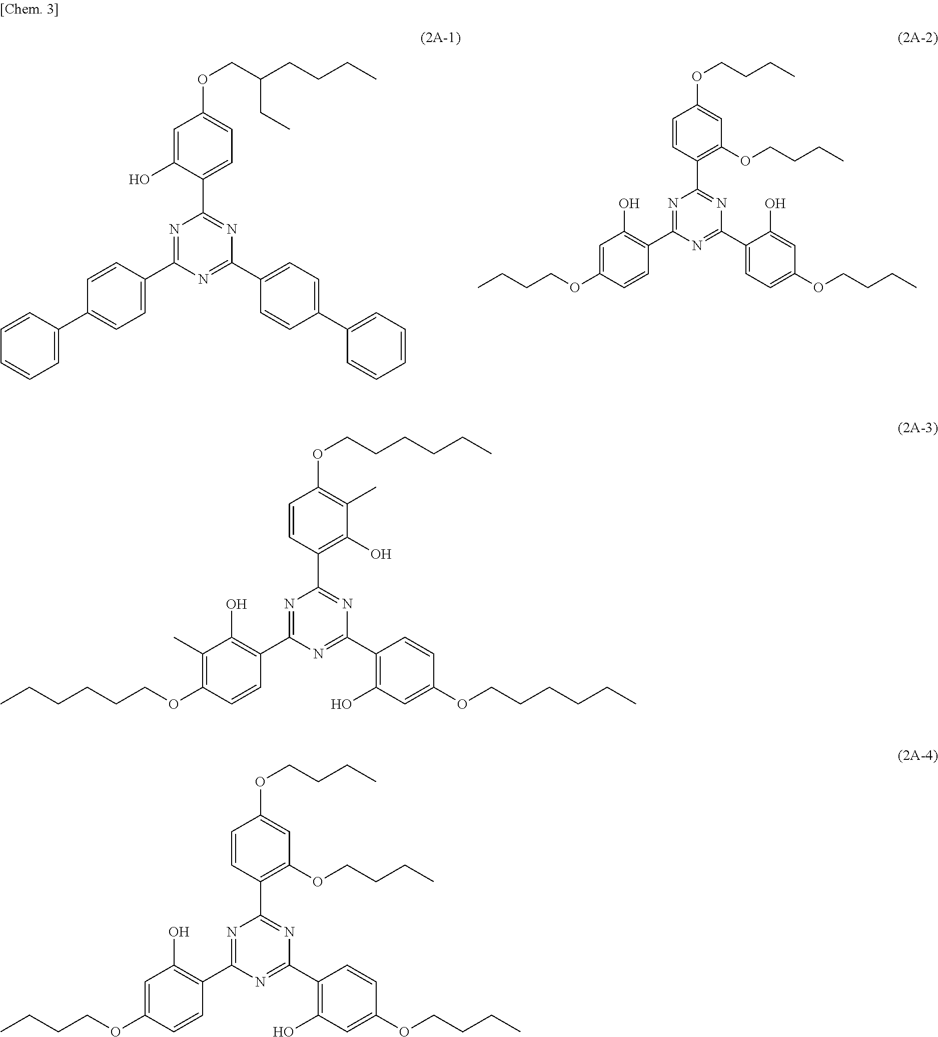

In the formula (2B), m is preferably 1 or 2.

In the formula, n1, n2, and n3 are each preferably 1 or 2, more preferably 1. Particularly preferably, one of n1, n2, and n3 is 0 while the remaining two of these are 1.

Specific examples of the compound represented by the formula (2B) include the compounds represented by any of the following formulas (2B-1) and (2B-2). A specific example of commercially available products of the compounds represented by these formulas is ADK STAB LA-31RG available from Adeka Corp.

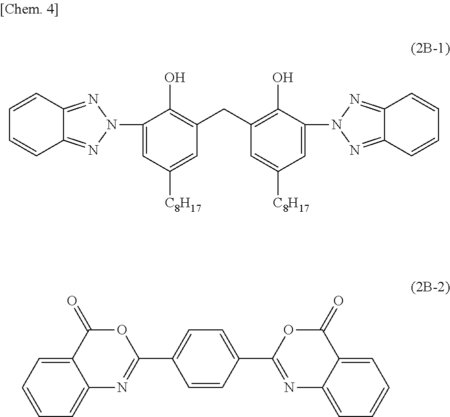

The amount of the nitrogen-containing heterocyclic compound is preferably 0.1% by mass or more, more preferably 0.5% by mass or more, still more preferably 1.0% by mass or more, while preferably 5.0% by mass or less, more preferably 4.0% by mass or less, still more preferably 3.0% by mass or less of the composition.

The composition of the disclosure has an absorbance of light with a wavelength of 355 nm of 0.6 or higher.

To achieve better UV laser processibility, the lower limit of the absorbance of light is preferably 0.7. The upper limit is not limited.

The absorbance of light is a value of a composition in the form of sheet having a thickness of 100 μm and is measured using a UV-VIS-NIR spectrophotometer (e.g., “V-770” available from Jasco Corp.) in the reflection geometry.

The composition of the disclosure contains preferably less than 2500 masses, more preferably not more than 2000 masses, still more preferably not more than 1000 masses of the nitrogen-containing heterocyclic compound having a size of 5 μm or greater per area of 1 mm² in image analysis by laser microscopic observation. The lower limit is not limited. This range may indicate that the nitrogen-containing heterocyclic compound is well dispersed and may lead to particularly good UV laser processibility.

The image analysis by laser microscopic observation is performed by the method to be described in the EXAMPLES below.

The composition of the disclosure may further contain a different component as appropriate. Examples of the different component include additives such as a filler, a cross-linker, an antistatic agent, a heat-resistance stabilizer, a foaming agent, a foam nucleating agent, an antioxidant, a surfactant, a photopolymerization initiator, an anti-wear agent, a surface modifier, a resin other than the modified fluororesin, and a liquid crystal polymer.

The different component preferably includes an inorganic filler. The presence of an inorganic filler can give effects of improving the strength and of reducing the linear expansion coefficient.

The inorganic filler preferably has no ultraviolet absorbency. The phrase “has no ultraviolet absorbency” means that the absorbance of light with a wavelength of 355 nm is lower than 0.1.

The absorbance of light is a value of powder of the inorganic filler packed to have a thickness of 100 μm and is measured using a UV-VIS-NIR spectrophotometer (e.g., “V-770” available from Jasco Corp.) in the reflection geometry.

The inorganic filler may preferably have a relative permittivity at 25° C. and 1 GHz of 5.0 or lower and a dissipation factor at 25° C. and 1 GHz of 0.01 or lower.

Specific examples of the inorganic filler include inorganic compounds such as silica (e.g., more specifically, crystalline silica, fused silica, spherical fused silica), titanium oxide, zirconium oxide, zinc oxide, tin oxide, silicon nitride, silicon carbide, boron nitride, calcium carbonate, calcium silicate, potassium titanate, aluminum nitride, indium oxide, alumina, antimony oxide, cerium oxide, magnesium oxide, iron oxide, and tin-doped indium oxide (ITO). Examples also include minerals such as montmorillonite, talc, mica, boehmite, kaolin, smectite, xonotlite, vermiculite, and sericite. Examples of other inorganic fillers include carbon compounds such as carbon black, acetylene black, ketjen black, and carbon nanotube; metal hydroxides such as aluminum hydroxide and magnesium hydroxide; and glasses such as glass beads, glass flakes, and glass balloons.

One of the fillers may be used or two or more thereof may be used.

The inorganic filler in the form of powder may be used as it is or may be dispersed in a resin before use.

To achieve excellent effects of improving the strength and of reducing the linear expansion coefficient, the inorganic filler preferably includes at least one selected from the group consisting of silica, boron nitride, talc, and aluminum hydroxide, and is particularly preferably silica.

The inorganic filler may have any shape, and may be in the form of particles, spheres, scales, needles, pillars, cones, pyramids, frustums, polyhedrons, or hollow matters, for example. Preferred among these are the forms of spheres, cubes, bowls, discs, octahedrons, scales, bars, plates, rods, tetrapods, and hollow matters, and more preferred are the forms of spheres, cubes, octahedrons, plates, and hollow matters. With the form of scales or needles, anisotropic filler pieces can be aligned to give higher adhesiveness. Spherical filler pieces are preferred because they have a small surface area and thus have a small influence on the properties of a fluororesin and less increase the viscosity when blended into a liquid.

In the case where the composition of the disclosure contains the inorganic filler, the amount of the inorganic filler is preferably 5% by mass or more, more preferably 10% by mass or more, while preferably 50% by mass or less, more preferably 30% by mass or less, still more preferably 20% by mass or less of the composition.

The inorganic filler preferably has an average particle size of 0.1 to 20 μm. The inorganic filler having an average particle size within this range is less likely to aggregate and can give good surface roughness. The lower limit of the average particle size is more preferably 0.2 μm, still more preferably 0.3 μm. The upper limit of the average particle size is more preferably 5 μm, still more preferably 2 μm.

The average particle size is a value determined by the laser diffraction scattering method.

The inorganic filler preferably has a maximum particle size of 10 μm or smaller. The inorganic filler having a maximum particle size of 10 μm or smaller is less likely to aggregate and can be well dispersed. Also, this inorganic filler allows the resulting fluororesin material to have a low surface roughness. The maximum particle size is more preferably 5 μm or smaller. The maximum particle size is determined from image data of 200 particles randomly selected in a SEM (scanning electron microscope) image using SEM image analysis software.

The inorganic filler may be surface-treated, and may be, for example, surface-treated with a silicone compound. This surface treatment with a silicone compound can reduce the permittivity of the inorganic filler.

The silicone compound used may be, but is not limited to, a conventionally known silicone compound. For example, the silicone compound preferably includes at least one selected from the group consisting of a silane-coupling agent and an organosilazane.

The amount of the silicone compound used for the surface treatment, which is expressed by the amount of the surface-treating agent reacted with the surface of the inorganic filler, is preferably 0.1 to 10 molecules, more preferably 0.3 to 7 molecules per unit surface area (nm²).

The inorganic filler preferably has a specific surface area by the BET method, for example, of 1.0 to 25.0 m²/g, more preferably 1.0 to 10.0 m²/g, still more preferably 2.0 to 6.4 m²/g. The inorganic filler having a specific surface area within this range is preferred because it is less likely to aggregate, and it allows the fluororesin material to have a smooth surface.

The composition of the disclosure can suitably be produced by a production method in which the fluororesin and the nitrogen-containing heterocyclic compound are melt-kneaded to provide the composition. The disclosure also provides this production method.

The composition of the disclosure may be produced by a method other than the above production method, such as injection molding, blow molding, inflation molding, or vacuum or pressure forming. In the case where the materials are dispersed or dissolved in a solvent, the composition may be produced by paste extrusion or casting.

Any device may be used for the melt-kneading, such as a twin-screw extruder, single-screw extruder, multi-screw extruder, or tandem extruder.

The duration of the melt-kneading is preferably 1 to 1800 seconds, more preferably 60 to 1200 seconds. Too long melt-kneading may impair the fluororesin, while too short melt-kneading may cause insufficient dispersion of the nitrogen-containing heterocyclic compound.

The temperature of the melt-kneading is not lower than the melting points of the fluororesin and the nitrogen-containing heterocyclic compound, and is preferably 240° C. to 450° C., more preferably 260° C. to 400° C.

The inventors found that the composition of the disclosure containing a fluororesin and a specific nitrogen-containing heterocyclic compound has excellent UV laser processibility and excellent electric properties (e.g., low permittivity) as well as good dispersibility. These characteristics are suitable for materials for circuit boards.

In other words, the composition of the disclosure can be suitably used as an insulating material of a circuit board or a dielectric material for a board.

The circuit board of the disclosure includes the aforementioned composition of the disclosure and a conductive layer.

The conductive layer used preferably contains a metal.

Examples of the metal include copper, stainless steel, aluminum, iron, silver, gold, and ruthenium. Alloys of any of these may also be used. Preferred is copper.

The copper used may be rolled copper or electrolytic copper.

The metal preferably has a surface having a surface roughness Rz of 2.0 μm or lower on a side facing the composition. This can lead to a good transmission loss when the composition and the metal are joined together.

The surface roughness Rz is more preferably 1.8 μm or lower, still more preferably 1.5 μm or lower, while more preferably 0.3 μm or higher, still more preferably 0.5 μm or higher.

The surface roughness Rz is a value calculated by the method of JIS C6515-1998 (maximum height roughness).

The conductive layer may have a thickness of 2 to 200 μm, preferably 5 to 50 μm, for example.

The conductive layer may be provided on one side of a layer containing the composition of the disclosure or may be provided on both sides thereof.

The layer containing the composition of the disclosure may have a thickness of 1 μm to 1 mm, preferably 1 to 500 μm, for example. The thickness is more preferably 150 μm or smaller, still more preferably 100 μm or smaller.

The circuit board of the disclosure is suitably used as a printed circuit board, a multilayer circuit board (multilayer board), or a high frequency board.

The high frequency circuit board is a circuit board that is operable in a high frequency band. The high frequency band may be a band of 1 GHz or higher, preferably a band of 3 GHz or higher, more preferably a band of 5 GHZ or higher. The upper limit may be, but is not limited to, a band of 100 GHz or lower.

The circuit board of the disclosure is preferably in the form of a sheet. The circuit board of the disclosure preferably has a thickness of 10 to 3500 μm, more preferably 20 to 3000 μm.

The disclosure (1) relates to a composition containing: a fluororesin; and a nitrogen-containing heterocyclic compound having a 1% by mass reduction temperature during pyrolysis of 330° C. or higher, and having an absorbance of light with a wavelength of 355 nm of 0.6 or higher (hereinafter, also referred to as the “composition of the disclosure”).

The disclosure (2) relates to the composition of the disclosure (1), wherein the nitrogen-containing heterocyclic compound is a non-polymeric compound.

The disclosure (3) relates to the composition of the disclosure (1) or (2), wherein the nitrogen-containing heterocyclic compound has a molecular weight of 1200 g/mol or lower.

The disclosure (4) relates to a composition combined with any one of the disclosures (1) to (3), wherein the nitrogen-containing heterocyclic compound contains a 3- to 10-membered nitrogen-containing heterocycle that contains a total of two or more nitrogen and oxygen atoms.

The disclosure (5) relates to a composition combined with any one of the disclosures (1) to (4), wherein the nitrogen-containing heterocyclic compound contains a nitrogen-containing heterocycle that is a triazine ring.

The disclosure (6) relates to a composition combined with any one of the disclosures (1) to (5), wherein the nitrogen-containing heterocyclic compound contains one to three nitrogen-containing heterocycles in one molecule of the nitrogen-containing heterocyclic compound.

The disclosure (7) relates to a composition combined with any one of the disclosures (1) to (6), wherein the nitrogen-containing heterocyclic compound contains an aromatic ring different from a nitrogen-containing heterocycle.

The disclosure (8) relates to the composition of the disclosure (7), wherein the nitrogen-containing heterocyclic compound contains one to five aromatic rings, each corresponding to the aromatic ring, in one molecule.

The disclosure (9) relates to the composition of the disclosure (7) or (8), wherein the nitrogen-containing heterocyclic compound is a compound having a structure represented by the following formula (1):

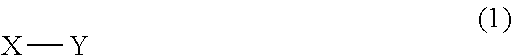

wherein X is a nitrogen-containing heterocycle; Y is an aromatic ring different from the nitrogen-containing heterocycle; and X and Y each optionally have a substituent.

The disclosure (10) relates to the composition of the disclosure (9), wherein the compound having a structure represented by the formula (1) is a compound represented by the following formula (2A) or a compound represented by the following formula (2B):

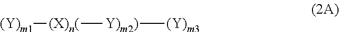

wherein X and Y are defined as in the formula (1); n is an integer of 1 to 3; m1, m2, and m3 are each an integer of 0 to 5, with at least one of m1, m2, or m3 being not 0; when multiple Xs are present, they are the same as or different from each other; and when multiple Ys are present, they are the same as or different from each other,

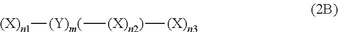

wherein X and Y are defined as in the formula (1); n1, n2, and n3 are each an integer of 0 to 3, with at least one of n1, n2, or n3 being not 0; m is an integer of 1 to 5; when multiple Xs are present, they are the same as or different from each other; and when multiple Ys are present, they are the same as or different from each other.

The disclosure (11) relates to a composition combined with any one of the disclosures (1) to (10), wherein the nitrogen-containing heterocyclic compound is contained in an amount of 0.1 to 5.0% by mass of the composition.

The disclosure (12) relates to a composition combined with any one of the disclosures (1) to (11), wherein the composition contains less than 2500 masses of the nitrogen-containing heterocyclic compound having a size of 5 μm or greater per area of 1 mm² in image analysis by laser microscopic observation.

The disclosure (13) relates to a composition combined with any one of the disclosures (1) to (12), wherein the fluororesin includes at least one selected from the group consisting of a tetrafluoroethylene/perfluoro (alkyl vinyl ether) copolymer and a tetrafluoroethylene/hexafluoropropylene copolymer.

The disclosure (14) relates to a composition combined with any one of the disclosures (1) to (13), wherein the fluororesin has a melting point of 240° C. to 320° C.

The disclosure (15) relates to a composition combined with any one of the disclosures (1) to (14), containing an inorganic filler.

The disclosure (16) relates to the composition of the disclosure (15), wherein the inorganic filler has no ultraviolet absorbency.

The disclosure (17) relates to the composition of the disclosure (15) or (16), wherein the inorganic filler has a relative permittivity at 25° C. and 1 GHz of 5.0 or lower and a dissipation factor at 25° C. and 1 GHz of 0.01 or lower.

The disclosure (18) relates to a composition combined with any one of the disclosures (15) to (17), wherein the inorganic filler is contained in an amount of 5 to 50% by mass of the composition.

The disclosure (19) relates to a composition combined with any one of the disclosures (1) to (18), which is an insulating material of a circuit board or a dielectric material for a board.

The disclosure (20) relates to a circuit board including: a composition combined with any one of the disclosures (1) to (19) and a conductive layer (hereinafter, also referred to as the “circuit board of the disclosure”).

The disclosure (21) relates to the circuit board of the disclosure (20), wherein the conductive layer contains metal.

The disclosure (22) relates to the circuit board of the disclosure (21), wherein the metal has a surface having a surface roughness Rz of 2.0 μm or lower on a side facing the composition.

The disclosure (23) relates to the circuit board of the disclosure (21) or (22), wherein the metal is copper.

The disclosure (24) relates to the circuit board of the disclosure (23), wherein the copper is rolled copper or electrolytic copper.

The disclosure (25) relates to a circuit board combined with any one of the disclosures (20) to (24), which is a printed circuit board, multilayer circuit board, or high frequency board.

The disclosure (26) also relates to a method for producing a composition combined with any one of the disclosures (1) to (19), the method including melt-kneading the fluororesin and the nitrogen-containing heterocyclic compound to provide the composition (hereinafter, also referred to as the “production method of the disclosure”).

### Examples

The disclosure is described in more detail below with reference to examples, but is not limited to these examples.

The materials used in the examples are as follows.

### (Fluororesin)

PFA (TFE/PAVE (% by mass): 94.6/5.4, melting point: 303° C., MFR: 14 g/10 min, relative permittivity (25° C., 10 GHz): 2.1, dissipation factor (25° C., 10 GHZ): 0.0003)
FEP (TFE/HFP (% by mass): 90/10, melting point: 270° C., MFR: 6 g/10 min, relative permittivity (25° C., 10 GHz): 2.1, dissipation factor (25° C., 10 GHz): 0.0015)

### (Nitrogen-Containing Heterocyclic Compound)

Compound represented by formula (2A-1) (non-polymeric nitrogen-containing heterocyclic compound, 1% pyrolysis temperature: 392° C., molecular weight: 606 g/mol)
Compound represented by formula (2A-3) (non-polymeric nitrogen-containing heterocyclic compound, 1% pyrolysis temperature: 384° C., molecular weight: 700 g/mol)
Compound represented by formula (2B-1) (non-polymeric nitrogen-containing heterocyclic compound, 1% pyrolysis temperature: 341° C., molecular weight: 659 g/mol)

### (Inorganic Filler)

Silica (no ultraviolet absorbency (absorbance of light with a wavelength of 355 nm: lower than 0.1), relative permittivity (25° C., 1 GHZ): 2.8, dissipation factor (25° C., 1 GHZ): 0.001, average particle size: 0.5 μm, specific surface area: 6.1 m2/g)

### Examples and Comparative Examples

A fluororesin, a nitrogen-containing heterocyclic compound, and an inorganic filler were melt-kneaded (duration: 600 seconds, temperature: 350° C.) at the ratio (% by mass) shown in Table 1 using a Labo Plastomill mixer, whereby a composition was obtained.

The resulting composition was extruded at the processing temperature shown in Table 1, whereby a sheet having the thickness shown in Table 1 was obtained.

In Example 9, the sheet obtained in Example 1 and copper foil (electrolytic copper, thickness: 18 μm, surface roughness Rz on a side to be joined to the sheet: 1.5 μm) were stacked and pressed at a heating temperature of 320° C. and a pressure of 15 kN for five minutes. Thereby, a joined article including the sheet joined to one side of the copper foil was obtained.

### (UV Laser Processibility)

The above sheet was irradiated with a UV laser under the following conditions and the state after the irradiation was evaluated. In Example 9, the UV laser was applied to the sheet in the joined article.
Pore size: 100 μm
Output: 2 W
Number of shots repeated: 7

The evaluation was based on the following criteria.
Excellent: completely pierced and no irregular hole shape observed
Good: partially pierced, or completely pierced but any irregular hole shape observed
Poor: not pierced

### (Number of Masses of Nitrogen-Containing Heterocyclic Compound (Image Analysis by Laser Microscopic Observation), Additive Dispersibility)

The number of masses of the nitrogen-containing heterocyclic compound having a size of 5 μm or greater per area of 1 mm² was evaluated by the following method.

A sample (sheet) was cut out with a razor and the cross section was observed with a laser microscope. For the number of masses of the nitrogen-containing heterocyclic compound, the number of masses per area of 0.008 mm² (length 0.08 mm, width 0.1 mm) in an image obtained at a magnification of 150 was counted, which was then converted into the number of masses per area of 1 mm².

The dispersibility of the additive (nitrogen-containing heterocyclic compound) was evaluated based on the following criteria.
Excellent: less than 2000 masses of the nitrogen-containing heterocyclic compound having a size of 5 μm or greater in image analysis by laser microscopic observation
Good: not less than 2000 but less than 2500 masses of the nitrogen-containing heterocyclic compound having a size of 5 μm or greater in image analysis by laser microscopic observation; evaluated as uniform in visual observation
Poor: not less than 2500 masses of the nitrogen-containing heterocyclic compound having a size of 5 μm or greater in image analysis by laser microscopic observation; evaluated as nonuniform in visual observation

### (Absorbance)

The absorbance of light with a wavelength of 355 nm of the sheet was measured using a UV-VIS-NIR spectrophotometer (“V-770” available from Jasco Corp.) in the reflection geometry. In Example 9, the absorbance of the copper clad laminate was not measured.

### (Relative Permittivity (Dk) and Dissipation Factor (Df))

The sheets of Example 5 and Comparative Example 1 were subjected to measurement of Dk and Df at 25° C. and 10 GHz using a split cylinder permittivity and dissipation factor measurement system (available from EM labs, Inc.). As a result, the sheet of Example 5 had a Dk value of 2.02 and a Df value of 0.00034, while the sheet of Comparative Example 1 had a Dk value of 2.08 and a Df value of 0.00031. This demonstrates that addition of the nitrogen-containing heterocyclic compound caused no significant reduction in the electric properties.

TABLE 1

| | | Example | | | | | | |
|---|---|---|---|---|---|---|---|---|
| | | 1 | 2 | 3 | 4 | 5 | 6 | 7 |
| Composition | PFA | 98 | | 98 | | 99 | | 95 |
| (mass %) | FEP | | 98 | | 98 | | 99 | |
| | Compound of Formula (2A-1) | 2 | 2 | | | 1 | 1 | 5 |
| | (1% pyrolysis temperature 392° C.) | | | | | | | |
| | Compound of Formula (2A-3) | | | 2 | | | | |
| | (1% pyrolysis temperature 384° C.) | | | | | | | |
| | Compound of Formula (2B-1) | | | | 2 | | | |
| | (1% pyrolysis temperature 341° C.) | | | | | | | |
| | Silica | | | | | | | |

| | | | | | | | |
|---|---|---|---|---|---|---|---|
| Copper clad laminate (one side, copper foil | No | No | No | No | No | No | No |
| thickness 18 μm) | | | | | | | |
| Processing temperature (° C.) | 350 | 300 | 350 | 300 | 350 | 300 | 350 |
| Thickness (μm) | 100 | 100 | 100 | 100 | 100 | 100 | 100 |
| UV laser processibility | Excellent | Excellent | Excellent | Excellent | Good | Good | Excellent |
| Additive dispersibility | Excellent | Excellent | Excellent | Excellent | Excellent | Excellent | Good |
| Number of masses of nitrogen-containing | 375 | 875 | 625 | 750 | 250 | 125 | 2150 |
| heterocyclic compound (/mm²) | | | | | | | |
| Absorbance | 1.4 | 1.5 | 1.5 | 1.0 | 1.0 | 1.2 | 1.7 |

| | | Example | | Comparative Example | | |
|---|---|---|---|---|---|---|
| | | 8 | 9 | 1 | 2 | 3 |
| Composition | PFA | 88 | 98 | 100 | | 90 |
| (mass %) | FEP | | | | 100 | |
| | Compound of Formula (2A-1) | 2 | 2 | | | |
| | (1% pyrolysis temperature 392° C.) | | | | | |
| | Compound of Formula (2A-3) | | | | | |
| | (1% pyrolysis temperature 384° C.) | | | | | |
| | Compound of Formula (2B-1) | | | | | |
| | (1% pyrolysis temperature 341° C.) | | | | | |
| | Silica | 10 | | | | 10 |

| | | | | | |
|---|---|---|---|---|---|
| Copper clad laminate (one side, copper foil | No | Yes | No | No | No |
| thickness 18 μm) | | | | | |
| Processing temperature (° C.) | 350 | 350 | 350 | 300 | 350 |
| Thickness (μm) | 100 | 100 | 100 | 100 | 100 |
| UV laser processibility | Excellent | Excellent | Poor | Poor | Poor |
| Additive dispersibility | Excellent | Excellent | — | — | — |
| Number of masses of nitrogen-containing | 250 | 250 | — | — | — |
| heterocyclic compound (/mm²) | | | | | |
| Absorbance | 1.2 | — | 0.4 | 0.4 | 0.4 |

1. A composition comprising:
a fluororesin having a melting point of 240° C. to 320° C.; and
a nitrogen-containing heterocyclic compound having a 1% by mass reduction temperature during pyrolysis of 330° C. or higher,
the composition having an absorbance of light with a wavelength of 355 nm of 0.6 or higher.

2. The composition according to claim 1,
wherein the nitrogen-containing heterocyclic compound is a non-polymeric compound.

3. The composition according to claim 1,
wherein the nitrogen-containing heterocyclic compound has a molecular weight of 1200 g/mol or lower.

4. The composition according to claim 1,
wherein the nitrogen-containing heterocyclic compound contains a 3- to 10-membered nitrogen-containing heterocycle that contains a total of two or more nitrogen and oxygen atoms.

5. The composition according to claim 1,
wherein the nitrogen-containing heterocyclic compound contains a nitrogen-containing heterocycle that is a triazine ring.

6. The composition according to claim 1,
wherein the nitrogen-containing heterocyclic compound contains one to three nitrogen-containing heterocycles in one molecule of the nitrogen-containing heterocyclic compound.

7. The composition according to claim 1,
wherein the nitrogen-containing heterocyclic compound contains an aromatic ring different from a nitrogen-containing heterocycle.

8. The composition according to claim 7,
wherein the nitrogen-containing heterocyclic compound contains one to five aromatic rings, each corresponding to the aromatic ring, in one molecule.

9. The composition according to claim 7,
wherein the nitrogen-containing heterocyclic compound is a compound having a structure represented by the following formula (1): 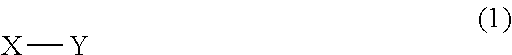
wherein X is a nitrogen-containing heterocycle; Y is an aromatic ring different from the nitrogen-containing heterocycle; and X and Y each optionally have a substituent.

10. The composition according to claim 9,
wherein the compound having a structure represented by the formula (1) is a compound represented by the following formula (2A) or a compound represented by the following formula (2B): 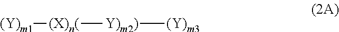
wherein X and Y are defined as in the formula (1); n is an integer of 1 to 3; m1, m2, and m3 are each an integer of 0 to 5, with at least one of m1, m2, or m3 being not 0; when multiple Xs are present, they are the same as or different from each other; and when multiple Ys are present, they are the same as or different from each other, 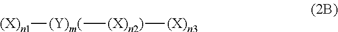
wherein X and Y are defined as in the formula (1); n1, n2, and n3 are each an integer of 0 to 3, with at least one of n1, n2, or n3 being not 0; m is an integer of 1 to 5; when multiple Xs are present, they are the same as or different from each other; and when multiple Ys are present, they are the same as or different from each other.

11. The composition according to claim 1,
wherein the nitrogen-containing heterocyclic compound is contained in an amount of 0.1 to 5.0% by mass of the composition.

12. The composition according to claim 1,
wherein the composition contains less than 2500 masses of the nitrogen-containing heterocyclic compound having a size of 5 μm or greater per area of 1 mm² in image analysis by laser microscopic observation.

13. The composition according to claim 1,
wherein the fluororesin includes at least one selected from the group consisting of a tetrafluoroethylene/perfluoro (alkyl vinyl ether) copolymer and a tetrafluoroethylene/hexafluoropropylene copolymer.

14. The composition according to claim 1, further comprising an inorganic filler.

15. The composition according to claim 14,
wherein the inorganic filler has no ultraviolet absorbency.

16. The composition according to claim 14,
wherein the inorganic filler is contained in an amount of 5 to 50% by mass of the composition.

17. The composition according to claim 1, which is an insulating material of a circuit board or a dielectric material for a board.

18. A circuit board comprising:
the composition according to claim 1; and
a conductive layer.

19. The circuit board according to claim 18,
wherein the conductive layer comprises metal.

20. The circuit board according to claim 19,
wherein the metal is copper.

21. The circuit board according to claim 19, which is a printed circuit board, multilayer circuit board, or high frequency board.

22. A method for producing the composition according to claim 1, the method comprising:
melt-kneading the fluororesin and the nitrogen-containing heterocyclic compound to provide the composition.
